(19) United States
(12) Patent Application Publication
(10) Pub. No.: US 2005/0047612 A1
(43) Pub. Date: Mar. 3, 2005

(54) Rotary manipulating apparatus

(75) Inventors: Masahiro Shimada, Kawasaki-shi (JP); Ichiro Chikano, Fujisawa-shi (JP)

Correspondence Address: JORDAN AND HAMBURG LLP, 122 EAST 42ND STREET, SUITE 4000, NEW YORK, NY, 10168, US

(73) Assignee: MARANTZ JAPAN, INC., Sagamihara-shi (JP)

(21) Appl. No.: 10/901,343

(22) Filed: Jul. 28, 2004

(30) Foreign Application Priority Data
Jul. 31, 2003 (JP) 2003-283722
Jul. 8, 2004 (JP) 2004-199190

(51) Int. Cl. H03G 3/00; G10D 9/00

(52) U.S. Cl. 381/104

(57) ABSTRACT

A rotary manipulating apparatus of a rotary type of which the action can be conducted with a definite sense of use is provided for, when installed in an electric or electronic instrument, simplifying the packaging of the electric or electronic instrument with packaging materials shaped and arranged not intricate and minimizing the damage in case that the instrument in the packaging suffers from any accidental collision during delivery.

The rotary manipulating apparatus includes a base 3 for mounting to the instrument, a manipulating means 4 for carrying out a rotating action, and a movable means 5 provided between the base 3 and the manipulating means 4 for slidably moving the manipulating means 4 or an input rotary shaft 6 for actuating the manipulating means 4 along the axial direction in relation to the base 3.

### BACKGROUND OF THE INVENTION

The present invention relates to a rotary manipulating apparatus arranged for rotating to carry out an electrical action, such as a switch for switching on and off by rotation or a volume control switch for controlling the magnitude of sound, which is commonly installed in an electric or electronic instrument as connected to relevant electric or electronic circuits in the same.

One of such conventional rotary manipulating apparatuses for rotating to carry out an electrical action is known as disclosed in the following citation.

Citation 1: Japanese Patent Laid-open Publication 2000-40442 (FIG. 1)

A touch type manipulating apparatus for carrying out an action upon being pressed down at the pressing surface is also known as the manipulating apparatus connected to an electric or electronic circuit in an electric or electronic instrument for switching the power supply on and off, controlling the amplitude of a signal, or the like.

The rotary manipulating apparatus is easier in the acknowledgment of a done action than the touch type and its action can thus be conducted with a definite sense of use.

However, each conventional rotary manipulating apparatus has a manipulating or control knob provided commonly on the front side thereof and may project outwardly at the front when installed in an electric or electronic instrument for connection to its relevant circuit.

As its manipulating knob remains projecting outwardly at the front, the rotary manipulating apparatus may allow the electric or electronic instrument to be packaged for delivery with much difficulty. This also makes the shape of an overall package intricate where an extra recess is required for holding the manipulating knob which projects outwardly.

Moreover, the package is reduced in the wall thickness at the recess for holding the manipulating knob. During the delivery, the manipulating knob projection outwardly may easily be injured by any accidental collision hence causing damage to the rotary manipulating apparatus.

Particularly, the injury of the knob by any accidental collision unlike a dent in the casing is seriously critical and may result in a malfunction of the rotary manipulating apparatus.

The present invention has been developed in view of the foregoing drawbacks and its object is to provide a rotary manipulating apparatus for enhancing the sense of use and ensuring each of the manipulating actions and particularly which can simplify the packaging of an electric or electronic instrument, where the apparatus is installed, with packaging materials shaped and arranged not intricate and also minimize the damage in case that the instrument in the packaging suffers from any accidental collision during delivery.

### SUMMARY OF THE INVENTION

A rotary manipulating apparatus according to the present invention is featured in which at least either a manipulating means or an input rotary shaft for actuating the manipulating means is slidable along the axial direction of the manipulating means in relation to the base.

More specifically, a rotary manipulating apparatus comprises a base, a manipulating means for carrying out a rotating action, and a movable means provided between the base and the manipulating means for slidably moving the manipulating means or/and an input rotary shaft for actuating the manipulating means along the axial direction of the manipulating means in relation to the base.

The rotary manipulating apparatus may be modified as a preferred embodiment in which, when installed in an electric or electronic instrument and electrically connected to its electric or electronic circuits, a manipulating knob is provided at the front end of the input rotary shaft for actuating the manipulating means and arranged movable between the projection position and the retracting position in the electric or electronic instrument.

The movable means in the rotary manipulating apparatus may comprise a male thread tube mounted to the manipulating means and having a male thread provided thereon coaxially with the manipulating means, a straight forward and backward guide arranged in mesh with a female thread tube mounted to the base for guiding the axial movement of the male thread tube while restricting the rotation of the male thread tube, the female thread tube provided between the male thread tube and the straight forward and backward guide and having a female thread provided therein for meshing with the male thread of the male thread tube, and a drive motor for rotating the female thread tube in both the forward and reverse directions.

In action, the rotary manipulating apparatus allows the manipulating knob at the front end of the input rotary shaft of the manipulating means to be selectively slid to a desired location by the movable means in relation to the base.

Accordingly, as the rotary manipulating apparatus is installed in an electric or electronic instrument, its manipulating knob can favorably be shifted between the projection position and the retracting position in the electric or electronic instrument.

The rotary manipulating apparatus according to the present invention allows the manipulating means or/and the input rotary shaft for actuating the manipulating means to be slidably moved along the axial direction of the manipulating means in relation to the base and when installed in an electric or electronic instrument, can simplify the packaging of the electric or electronic instrument with packaging materials shaped and arranged not intricate and minimize the damage in case that the instrument in the packaging suffers from any accidental collision during delivery, hence ensuring the clear sense of use for carrying out each manipulating action with certainty.

### BRIEF DESCRIPTION OF THE DRAWINGS

FIG. 1 is a partially cutout schematic view illustrating a first embodiment of the present invention at one function mode installed in an audio amplifier;

FIG. 2 is a perspective view of the audio amplifier where the first embodiment shown in FIG. 1 is installed;

FIG. 3 is a partially cutout schematic view of the first embodiment, shown in FIG. 1, at another function mode installed in the audio amplifier;

FIG. 4 is a perspective view of the audio amplifier where the first embodiment shown in FIG. 3 is installed;

FIG. 5 is a schematic view, similar to FIG. 1, illustrating a second embodiment of the present invention installed in an audio amplifier;

FIG. 6 is a view, similar to FIG. 3, of the second embodiment shown in FIG. 5;

FIG. 7 is a perspective view illustrating the construction of a holding member in the second embodiment shown in FIGS. 5 and 6; and

FIG. 8 is a schematic view, similar to FIG. 7, of the second embodiment of a holding member.

### DETAILED DESCRIPTION OF THE PREFERRED EMBODIMENTS

The present invention will be described in the form of preferred embodiments referring to the relevant drawings. It is noted that the present invention is not limited to the described embodiments.

A first embodiment of the present invention is provided which is connected to an electric circuit as installed in an electric or electronic instrument.

A rotary manipulating apparatus 1 of the first embodiment is a volume controller connected to a circuit as installed in an audio amplifier 2 which acts as the electric or electronic instrument.

The rotary manipulating apparatus 1 comprises a base 3, a manipulating means 4, and a movable means 5.

The base 3 is arranged of substantially a cylindrical shape having through holes( not shown ) across which an input rotary shaft 6 extends for actuating the manipulating means 4.

The base 3 has a mounting region provided at the front for mounting to the audio amplifier 2 and is anchored by screws to a holder plate 7 of the audio amplifier 2. More specifically, the base 3 has a function for anchoring the housing of the rotary manipulating apparatus 1 to the electric or electronic instrument.

The manipulating means 4 is mounted on the rear of the base 3.

The manipulating means 4 is a rotary encoder for controlling the signal output through rotation and functionally acts as a volume controller for controlling the magnitude of a sound output of the audio amplifier 2.

The input rotary shaft 6 is arranged to extend through substantially the center of the manipulating means 4 and has a manipulating knob 8 mounted to the front end thereof for controlling.

The input rotary shaft 6 is slidable in both directions denoted by the arrows A and B in relation to the housing of the manipulating means 4 or the base 3.

The rotary manipulating apparatus 1 is installed in the audio amplifier 2 so that its manipulating knob 8 can extend outwardly from the through hole 10 provided in a front operation panel 9.

The movable means 5 in the rotary manipulating apparatus 1 is provided between the base 3 and the manipulating means 4 for sliding the input rotary shaft 6 along the axial direction of the manipulating means 4 (denoted by the arrows A and B) in relation to the base 3.

The movable means 5 comprises a male thread tube 12 mounted on the input rotary shaft 6 of the manipulating means 4 and having a male thread 11 arranged on a side thereof to extend coaxial with the input rotary shaft 6, a straight forward and backward guide 13 mounted to the base 3 and arranged for engagement with a female thread tube 15 to guide the axial movement of the male thread tube 12 while restricting the rotation of the male thread tube 12, the female thread tube 15 mounted between the male thread tube 12 and the straight forward and backward guide 13 and having a female thread 14 arranged for engagement with the male thread 11 of the male thread tube 12, and a step type drive motor 16 for rotating the female thread tube 15 in both, forward and backward, directions.

The input rotary shaft 6 extends coaxially across the male thread tube 12. The input rotary shaft 6 and the male thread tube 12 are coupled to each other by a bearing 17.

The input rotary shaft 6 has a pair of E rings 25 fitted thereon to sandwich the bearing 17. The E rings 25 are arranged to slide together with the male thread tube 12 along the directions denoted by the arrows A and B.

The male thread tube 12 has a recess 18 provided coaxially of the male thread tube 12 in the outer side thereof to extend from the front end to substantially the center of the male thread tube 12.

The straight forward and backward guide 13 has a projection 19 provided thereon to engage with the recess 18 of the male thread tube 12. The projection 19 guides the axial movement (along the directions denoted by the arrows A and B) of the male thread tube 12 while restricting the rotation of the male thread tube 12.

Also, the straight forward and backward guide 13 has an accommodating space 20 arranged for accommodating the female thread tube 15 while restricting the axial movement of the female thread tube 15.

The female thread tube 15 has a toothed wheel 21 provided on the outer side thereof.

The toothed wheel 21 is arranged in mesh with a gear 22 mounted to an output shaft (not shown) for transmitting the rotating power from the drive motor 16 to the female thread tube 15.

The audio amplifier 2 also includes a manipulating knob 23 which can frontwardly project from the front operating panel 9 when it is turned for selecting the function of the audio amplifier 2.

The manipulating knob 23 like the manipulating knob 8 of the rotary manipulating apparatus 1 is arranged to move between the projecting position and the retracting position in the front operating panel 9.

An openable door 24 is hinged to the lower end at the center of the front operating panel 9 of the audio amplifier 2. When the openable door 24 is open, a display and an array of button switches (all not shown) become visible and accessible for controlling.

The rotary manipulating apparatus 1 and the audio amplifier 2 where the rotary manipulating apparatus 1 is installed are constructed in the above described arrangement.

The action of those will now be explained.

When the audio amplifier 2 has manufactured, tested, and determined that it is good at a manufacturer's plant, the drive motor 16 is actuated to drive the movable means 5 for retracting the manipulating knob 8 into the retracting position in the audio amplifier 2 before the delivery.

More specifically, the drive motor 16 drives the gear 22 and the toothed wheel 21 to rotate the female thread tube 15 in the forward direction.

The female thread tube 15 is rotated in the forward direction by the toothed wheel 21 being driven in the same direction. As the female thread tube 15 rotates in the forward direction, the male thread tube 12 having the male thread 11 meshed with the female thread 14 of the female thread tube 15 attempts to rotate in the same direction.

However, the male thread tube 12 has the recess 18 engaged with the projection 19 of the straight forward and backward guide 13 and its rotation is interrupted by the engagement between the recess 18 and the projection 19.

Meanwhile, since the female thread tube 15 is held in the accommodating space 20 of the straight forward and backward guide 13, it can remain not moved in either the direction A or B.

Accordingly, the male thread tube 12 is relatively urged by a counter force of the female thread tube 15 which remains not moved in either the direction A or B and can thus travel in the direction A.

As the male thread tube 12 is traveled into its rearmost position in the female thread tube 15, it actuates a limiter switch (not shown) for switching the drive motor 16 off.

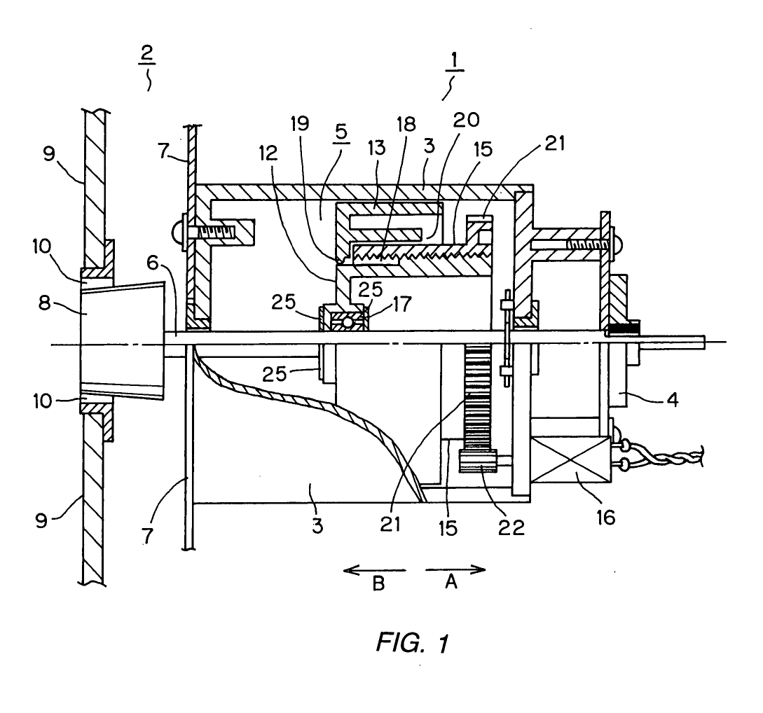

This causes the input rotary shaft 6 coupled integral with the male thread tube 12 along the directions A and B to slide by the same distance of the male thread tube 12 in the direction A. As a result, the manipulating knob 8 is moved by the same distance in the direction A and held in the retracting position in the audio amplifier 2 shown in FIG. 1.

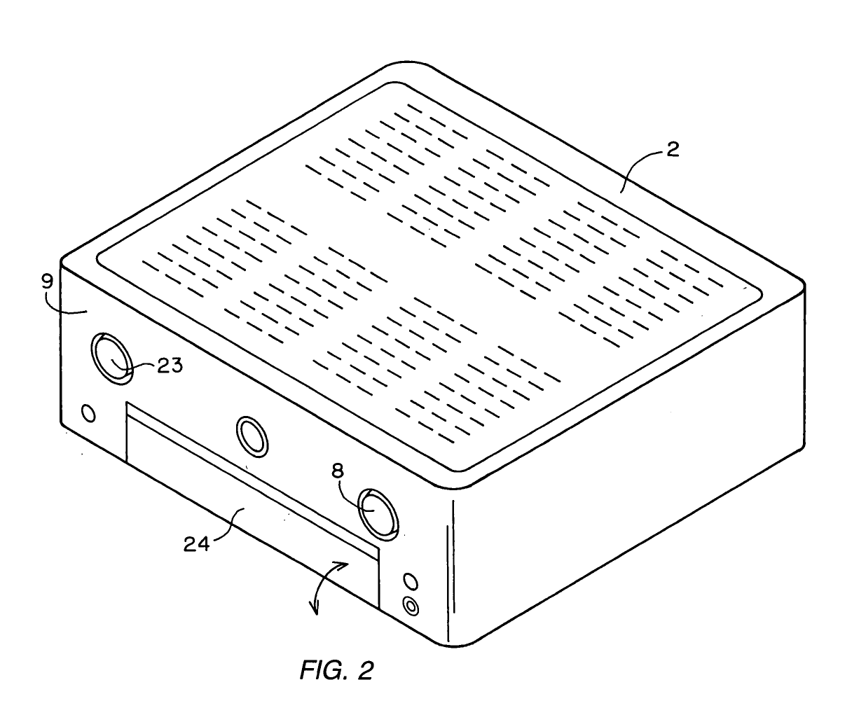

This is followed at the manufacturer's plant by conducting the same procedure as of the manipulating knob 8 to hold the manipulating knob 23 on the front operation panel 9 in its retracting position in the audio amplifier 2. After confirmation of the openable door 24 remaining at its closed position (See FIG. 2), the audio amplifier 2 is wrapped with a packaging sheet.

The audio amplifier 2 wrapped in the packaging sheet is then packaged with packaging forms (not shown) of a foamed material which are shaped and sized to match the dimensions of the audio amplifier 2.

The audio amplifier 2 in the packaging forms is finally loaded into a cardboard box for the delivery.

With its front operation panel 9 remaining substantially flat where the two manipulating knobs 8 and 23 are not projected but at their retracting position, the audio amplifier 2 has no disturbing sides and can be wrapped without difficulty by the packaging sheet.

Also, the packaging forms of the foamed material need not to have any recesses for accepting the disturbing projections such as the manipulating knobs 8 and 23 because the manipulating knobs 8 and 23 at the front operation panel 9 remain at their retracting position in the audio amplifier 2. Accordingly, the packaging forms can be shaped and sized with much ease as compared with the manipulating knobs 8 and 23 projecting from the front operation panel 9.

Moreover, in case that the audio amplifier 2 in its packaged state or not encounters an accidental collision during the delivery, its front operation panel 9 has the manipulating knobs 8 and 23 held at their retracting position and can thus protect the manipulating knobs 8 and 23 from any critical impact caused by the collision while the casing (not shown) of the audio amplifier 2 cushions the impact.

Consequently, as the manipulating knob 8 is prevented from receiving any critical impact, the manipulating means 4 and thus the audio amplifier 2 can remain free from undesired impact hence hardly being malfunctioned.

Equally, the manipulating knob 23 is protected.

Then, the audio amplifier 2 is received and unpacked by a user before being placed, e.g., on an AV rack (not shown).

When the drive motor 16 is switched on by the user, it drives the movable means 5 so that the manipulating knob 8 moves out from the audio amplifier 2.

More particularly, the drive motor 16 drives the gear 22 and the toothed wheel 21 to rotate the female thread tube 15 in the reverse direction.

The female thread tube 15 is rotated in the same direction as of the toothed wheel 21. As the female thread tube 15 rotates in the reverse direction, the male thread tube 12 having the male thread 11 meshed with the female thread 14 is rotated in the same direction.

However, the male thread tube 12 has the recess 18 engaged with the projection 19 of the straight forward and backward guide 13 and its rotation is interrupted by the engagement between the recess 18 and the projection 19.

Meanwhile, since the female thread tube 15 is held in the accommodating space 20 of the straight forward and backward guide 13, it can remain not moved in either the direction A or B.

Accordingly, the male thread tube 12 is relatively urged by a counter force of the female thread tube 15 which remains not moved in either the direction A or B and can thus travel in the direction B. As the male thread tube 12 is moved out from the female thread tube 15 by a given distance, it actuates a limiter switch (not shown) for switching the drive motor 16 off.

This causes the input rotary shaft 6 coupled integral with the male thread tube 12 along the directions A and B to slide by the same distance as of the male thread tube 12 in the direction B. As a result, the manipulating knob 8 is advanced in the direction B.

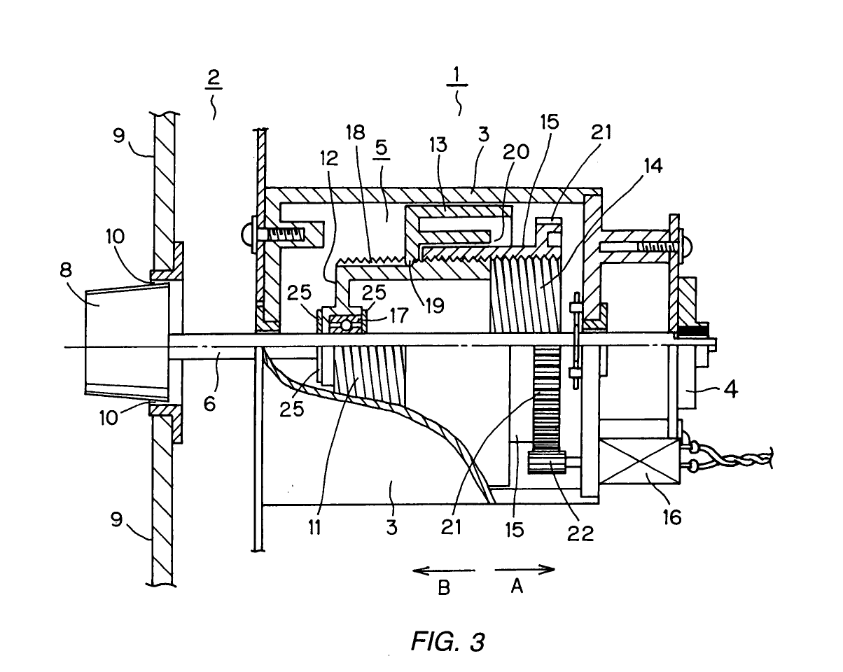

The manipulating knob 8 is now projected out from the front operating panel 9 of the audio amplifier 2 as shown in FIG. 3.

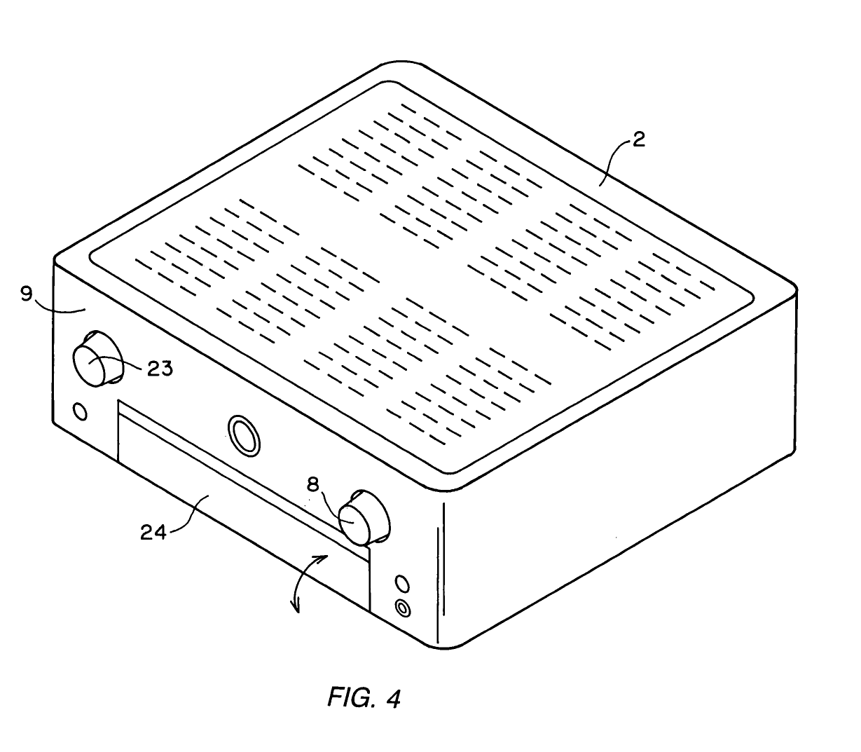

The manipulating knob 23 is also projected from the front operating pane 19 by the user conducting the same manner as for the manipulating knob 8 (See FIG. 4).

The audio amplifier 2 may thus be played by the user controlling the manipulating knobs 8 and 23 and operating the button switches with the openable door 24 being open.

Since the manipulating knobs 8 and 23 in the audio amplifier 2 are of a rotary type, their use can certainly be sensed and acknowledged with much ease as compared with a touch type of the manipulating apparatus (means).

Although the input rotary shaft 6 is slidably moved along the directions A and B in relation to the base 3 in the rotary manipulating apparatus 1, the manipulating means 4 may be slid along the directions A and B in relation to the base 3.

Alternatively, both the manipulating means 4 and the input rotary shaft 6 may slidably be moved along the directions A and B in relation to the base 3 so that the overall movement of the manipulating knob 8 can be increased in length.

The rotary manipulating apparatus 1 of this embodiment serves as a sound volume controller while the rotary manipulating means linked to the manipulating knob 23 is a selector switch for selecting the function of the audio amplifier 2. They may be used in a combination for tuning, selecting the tone, determining the left/right balance of an output, or conducting any other function.

While the manipulating knobs 8 and 23 are located at the retracting position shown in FIGS. 1 and 2 and at the projecting position shown in FIGS. 3 and 4 according to the embodiment of the rotary manipulating apparatus 1, they may be used at their intermediate location between the retracting position and the projecting position if desired.

As the manipulating knobs 8 and 23 are selectively located at the intermediate location, their extension in relation to the overall size of the audio amplifier 2 can favorably be controlled for giving an optimum appearance.

The movable means 5 in the rotary manipulating apparatus 1 comprises the male thread tube 12 linked to the manipulating means 4, the straight forward and backward guide 13 mounted to the base 3, the female thread tube 15 arranged in mesh with the male thread tube 12 between the male thread tube 12 and the straight forward and backward guide 13, and the drive motor 16 for rotating the female thread tube 15 in both the forward and reverse direction. Alternatively, a linear motor, a solenoid, or any other appropriate means may be used for slidably moving the manipulating means 4 and/or the input rotary shaft 6 along the directions A and B in relation to the base 3.

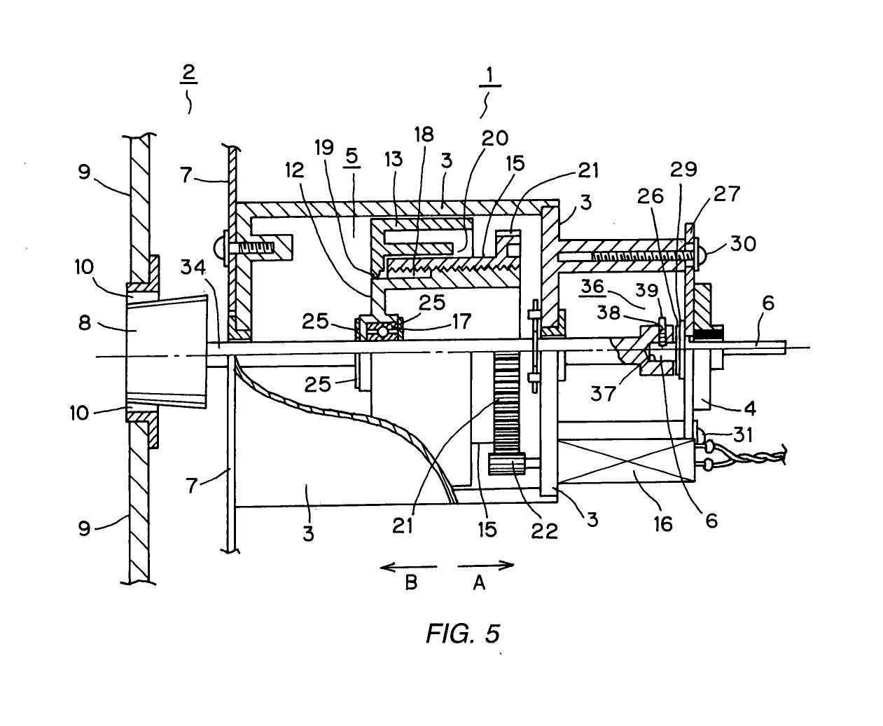

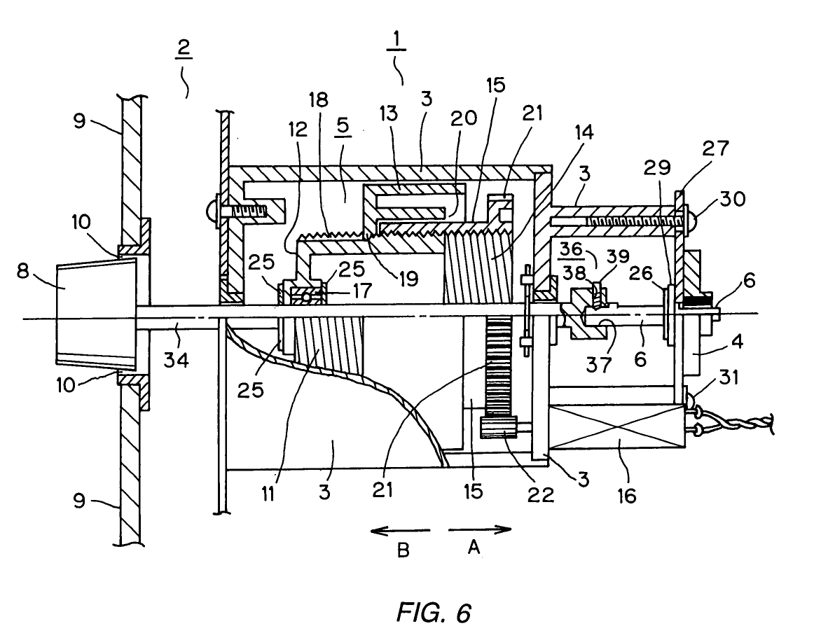

A second embodiment of the present invention will now be described referring to FIGS. 5 and 6.

The second embodiment is differentiated from the first embodiment by the fact that the manipulating means 4 is modified where the input rotary shaft 6 is coupled by a connecting means 36 to a manipulating shaft 34. As the length of the input rotary shaft 6 of the manipulating means 4 is shortened with the manipulating shaft 34 of a desired length coupled thereto, the manipulating means 4 can be improved in the general use and its operable position (at the manipulating knob 8) can selectively be determined.

While the same arrangement of the second embodiment as of the first embodiment is not explained, the features of the second embodiment only will be described in more detail.

A rotary manipulating apparatus 1 of the second embodiment is a volume controller connected to a circuit as installed in an audio amplifier 2.

The rotary manipulating apparatus 1 comprises a base 3, a manipulating means 4 which is an encoder, and a movable means 5.

The base 3 is arranged of substantially a cylindrical shape having through holes (not shown) across which the manipulating shaft 34 extends for actuating the

The manipulating means 4 has an input rotary shaft 6 arranged to extend through substantially the center thereof for rotating to carry out an input operation. The input rotary shaft 6 is slidable in its axial directions (denoted by the arrows A and B) in relation to the manipulating means 4.

The manipulating means 4 has a male thread 26 provided on the front end thereof to extend coaxially of the input rotary shaft 6.

The male thread 26 is inserted through a hole 28 provided in a holding member 27 and joined with a nut 29 via a washer (not shown) so that the manipulating means 4 is securely mounted to the holding member 27.

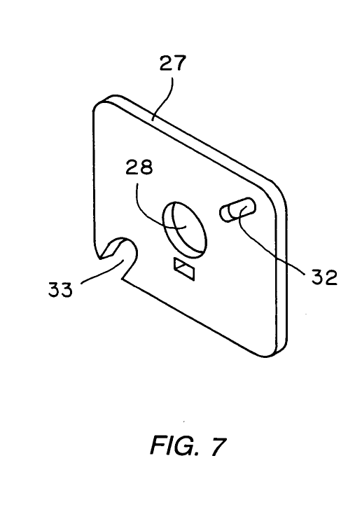

The holding member 27 has, as best shown in FIG. 7, a through hole 32 and a notch 33 provided therein across which screws 30 and 31 are inserted for screwing into the rear of the base 3.

The through hole 32 in the holding member 27 is arranged of substantially an oval shape which extends radially of the through hole 28 as shown in FIG. 7.

The notch 33 in the holding member 27 is arranged greater in the diameter than the screw 30 and opened at the outward end.

The holding member 27 having the through hole 32 and the notch 33 provided therein in the foregoing arrangement allows the screws 30 and the 31 to be selectively located along the plane of the back side of the base 3 in the hole 32 and the notch 33 respectively for positioning the holding member 27 in relation to the base 3.

The manipulating shaft 34 for controlling the manipulating means 4 is pivotably coupled to the input rotary shaft 6 at the front of the manipulating means 4 for slidable movement along the axial directions A and B.

The coupling between the manipulating shaft 34 and the input rotary shaft 6 in the manipulating means 4 is coaxially made by the connecting means 36.

The connecting means 36 comprises a fitting recess 37 provided in the rear end of the manipulating shaft 34 to have a columnar space coaxially of the manipulating shaft 34, the input rotary shaft 6 of the manipulating means 4 for coaxially fitting into the fitting recess 37, and a holding means for holding the input rotary shaft 6 in the fitting recess 37.

The holding means may commonly comprise a female thread hole 38 provided radially in the rear end at the fitting recess 37 of the manipulating shaft 34 and a screw 39 screwed into the female thread hole 38.

Accordingly, with the manipulating shaft 34 and the input rotary shaft 6 of the manipulating means 4 coaxially coupled to each other by the connecting means 36, the holding member 27 securing the manipulating means 4 remains held at a some position to the base 3. This enables the manipulating means 4 to be fixed to the base 3 by screwing two screws 30 and 31 into their respective female threads (not shown) of the base 3 with the manipulating shaft 34 and the input rotary shaft 6 being axially aligned with each other while the holding member 27 remains held at the said position to the base 3.

Similar to the first embodiment, the rotary manipulating apparatus 1 of the second embodiment in the audio amplifier 2 has a movable means 5 for slidably moving the manipulating shaft 34 along the axial directions.

The movable means 5 in the second embodiment is identical in the construction and the function to that in the first embodiment.

More particularly, the manipulating knob 8 mounted to the distal end of the manipulating shaft 34 can selectively be moved between the retracting position and the projecting position across the front operating panel 9 of the audio amplifier 2 by controlling the movable means 5.

The rotary manipulating apparatus 1 of this embodiment serves as a sound volume controller while the rotary manipulating means linked to the manipulating knob 23 is a selector switch for selecting the function of the audio amplifier 2. They may be used in a combination for tuning, selecting the tone, determining the left/right balance of an output, or conducting any other function.

Although the connecting means 36 in this embodiment comprises the fitting recess 37 provided in the rear end of the manipulating shaft 34, the input rotary shaft 6 of the manipulating means 4, and the connecting means provided with the female thread holes 38, it may be constructed by the fitting recess 37 provided in the rear end of the manipulating shaft 34, the input rotary shaft 6 of the manipulating means 4, and a cylindrical bushing provided between the fitting recess 37 and the input rotary shaft 6.

The latter arrangement also permits both the manipulating shaft 34 and the input rotary shaft 6 to be slid along the two directions A and B. It is hence necessary to provide a connecting means for connecting between the manipulating means 34 and the input rotary shaft 6.

The through hole 32 and the notch 33 provided in the holding member 27 are determined in the size and shape so that the holding member 27 can be mounted to the base 3 with the manipulating shaft 34 and the input rotary shaft 6 remaining coaxially coupled to each other.

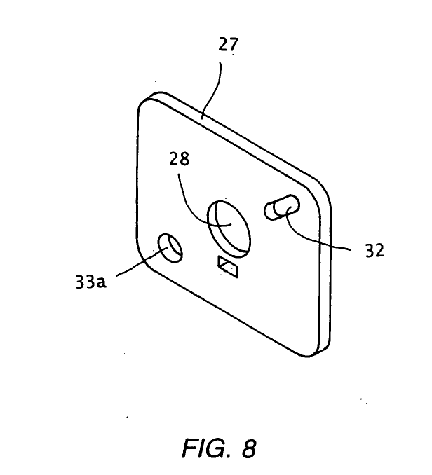

Also, the notch 33 provided in the holding member 27, as shown in FIG. 8, may be modified to a through hole 33a which is greater enough in the diameter than the screw 31.

1. A rotary manipulating apparatus comprising a base, a manipulating means for carrying out a rotating action, and a movable means provided between the base and the manipulating means for slidably moving the manipulating means or/and an input rotary shaft for actuating the manipulating means along the axial direction of the manipulating means in relation to the base.

2. A rotary manipulating apparatus comprising a base, a manipulating means for carrying out a rotating action, and a movable means provided between the base and the manipulating means for slidably moving the manipulating means or/and an input rotary shaft for actuating the manipulating means along the axial direction of the manipulating means in relation to the base, the movable means including a male thread tube mounted to the manipulating means and having a male thread provided thereon coaxially with the manipulating means, a straight forward guide mounted to the base and arranged in mesh with a female thread tube for guiding the axial movement of the male thread tube while restricting the rotation of the male thread tube, the female thread tube provided between the male thread tube and the straight forward guide and having a female thread provided therein for meshing with the male thread of the male thread tube, and a drive motor for rotating the female thread tube in both the forward and reverse directions.

3. A rotary manipulating apparatus according to claim 1 or 2, wherein when installed in an electric or electronic instrument, the manipulating shaft for actuating the manipulating means has a manipulating knob provided at the front end thereof and the manipulating knob is movable between the projecting position and the retracting position in the electric or electronic instrument.

4. A rotary manipulating apparatus comprising a base, a manipulating means for carrying out a rotating action, and a movable means provided between the base and the manipulating means for slidably moving the manipulating means or/and an input rotary shaft for actuating the manipulating means along the axial direction of the manipulating means in relation to the base, the rotary manipulating apparatus further comprising a manipulating shaft provided separately of the input rotary shaft of the manipulating means and arranged to connect with the input rotary shaft for actuating the manipulating means, a connecting means for connecting coaxially between the manipulating shaft and the input rotary shaft, and a holding member for holding and securing the manipulating means to the base, wherein the holding member can be tightened to the base with the input rotary shaft and the manipulating shaft being connected coaxially to each other by the connecting means.

5. A rotary manipulating apparatus comprising a base, a manipulating means for carrying out a rotating action, and a movable means provided between the base and the manipulating means for slidably moving the manipulating means or/and an input rotary shaft for actuating the manipulating means along the axial direction of the manipulating means in relation to the base, the movable means including a male thread tube mounted to the manipulating means and having a male thread provided thereon coaxially with the manipulating means, a straight forward guide mounted to the base and arranged in mesh with a female thread tube for guiding the axial movement of the male thread tube while restricting the rotation of the male thread tube, the female thread tube provided between the male thread tube and the straight forward guide and having a female thread provided therein for meshing with the male thread of the male thread tube, and a drive motor for rotating the female thread tube in both the forward and reverse directions, the rotary manipulating apparatus further comprising a manipulating shaft provided separately of the input rotary shaft of the manipulating means and arranged to connect with the input rotary shaft for actuating the manipulating means, a connecting means for connecting coaxially between the manipulating shaft and the input rotary shaft, and a holding member for holding and securing the manipulating means to the base, wherein the holding member can be fixed to the base with the input rotary shaft and the manipulating shaft being connected coaxially to each other by the connecting means.

6. A rotary manipulating apparatus according to claim 4 or 5, wherein the tightening of the holding member to the base with the input rotary shaft and the manipulating shaft being connected coaxially to each other by the connecting means involves joining by screws to the base the holding member which has through holes or notches provided therein across which screws are inserted and tightened, while the through holes or notches provided in the holding member are sized and shaped so that the holding member can be slid in relation to the base with the input rotary shaft and the manipulating shaft being connected coaxially to each other by the connecting means.

7. A rotary manipulating apparatus according to claim 4 or 5, wherein the connecting means is a bushing for fitting at one end to one of the input rotary shaft and the manipulating shaft of the manipulating means and at the other end to the other.

8. A rotary manipulating apparatus according to claim 4 or 5, wherein when installed in an electric or electronic instrument, the manipulating shaft for actuating the manipulating means has a manipulating knob provided at the front end thereof and the manipulating knob is movable between the projecting position and the retracting position in the electric or electronic instrument.
